(19) United States
(12) Patent Application Publication
(10) Pub. No.: US 2026/0190964 A1
(43) Pub. Date: Jul. 2, 2026

(54) CHIP PACKAGE STRUCTURE, METHOD FOR PREPARING CHIP PACKAGE STRUCTURE, AND ELECTRONIC DEVICE

(71) Applicant: TCL CHINA STAR OPTOELECTRONICS TECHNOLOGY CO., LTD., Shenzhen (CN)

(72) Inventors: Libin ZHOU, Shenzhen (CN); Zhifu LI, Shenzhen (CN); Jianfeng YUAN, Shenzhen (CN); Rui ZHAO, Shenzhen (CN)

(73) Assignee: TCL CHINA STAR OPTOELECTRONICS TECHNOLOGY CO., LTD., Shenzhen (CN)

(21) Appl. No.: 19/185,217

(22) Filed: Apr. 21, 2025

(30) Foreign Application Priority Data
Dec. 30, 2024 (CN) 202411992002.3

(51) Int. Cl. H01L 23/48; H01L 23/00; H01L 23/538; H01L 25/00; H01L 25/18; H10D 1/20; H10D 1/47; H10D 1/68

(52) U.S. Cl. CPC H10W 20/20; H10W 70/611; H10W 70/65; H10W 90/00; H10D 1/20; H10D 1/47; H10D 1/68; H10W 72/07236; H10W 72/07336; H10W 72/856; H10W 90/722; H10W 90/724; H10W 90/732; H10W 99/00

(57) ABSTRACT

A chip package structure, a method for preparing a chip package structure and an electronic device are provided. The chip package structure includes a substrate layer, and a rewiring layer and a chip stacking layer sequentially disposed on the substrate layer, and the chip stacking layer includes at least one chip stacking unit. The chip stacking unit includes a first chip, and one or more second chips located between the first chip and the rewiring layer. The chip package structure further includes at least one first through-hole penetrating each second chip, a conductive pillar is filled in the first through-hole, any one of the chips is connected to the conductive pillar in the adjacent second chip, and the first chip is electrically connected to the second chip and/or the rewiring layer through the conductive pillar.

### CROSS-REFERENCE TO RELATED APPLICATION

This application claims priority to and the benefit of Chinese Patent Application No. 202411992002.3, filed on Dec. 30, 2024, the disclosure of which is incorporated herein by reference in its entirety.

### TECHNICAL FIELD

The present disclosure relates to the field of semiconductor packaging technology, and in particular, to a chip package structure, a method for preparing a chip package structure, and an electronic device.

### BACKGROUND

With the development of technologies of artificial intelligence (AI) chips and high performance computing (HPC), the amount of integrated transistors in a chip has reached 100 billion, and it is estimated that 1 trillion transistors will need to be integrated by 2030. However, current chip packaging technology cannot meet the requirements of high-performance chips. For example, wafer packaging is used for the chip-on-wafer-on-substrate (CoWos) process in a wafer foundry, in which it is very difficult to increase the size of the wafer. At present, the diameter of the wafer is up to about 300 millimeters (mm), which cannot meet the requirements of high-performance chips.

### SUMMARY

The embodiments of the present disclosure provide a chip package structure, a method for preparing a chip package structure, and an electronic device, mutual communication among a plurality of chips that are stacked and/or between a plurality of chips and a rewiring layer are realized through a through-hole process, thereby realizing integration of the chips with high-density and meeting the requirements of high-performance chips.

To achieve the above object, a first aspect of the present disclosure provides a chip package structure including:
a substrate layer;
a rewiring layer disposed on one side of the substrate layer; and
a chip stacking layer disposed on a side of the rewiring layer away from the substrate layer and including at least one chip stacking unit; the chip stacking unit includes a first chip and one or more second chips located between the first chip and the rewiring layer, and the first chip and the one or more second chips are at least partially overlapped in a thickness direction of the substrate layer;
the chip package structure further includes at least one first through-hole penetrating each second chip, a conductive pillar is filled in the first through-hole, any one of the first chip and the one or more second chips is connected to the conductive pillar in the second chip adjacent thereto, and the first chip is electrically connected to the second chip and/or the rewiring layer through the conductive pillar.

In some embodiments, a first conductive connection layer is disposed between the first chip and the second chip adjacent thereto, and the first conductive connection layer is connected to the conductive pillar in the second chip adjacent thereto;
a second conductive connection layer is disposed between the second chip close to the rewiring layer and the rewiring layer, and the second conductive connection layer includes a first conductive connection portion and a second conductive connection portion that are located between a corresponding the second chip and the rewiring layer and are spaced apart; the first conductive connection portion is electrically connected to the second chip adjacent thereto and the rewiring layer, respectively, and the second conductive connection portion is electrically connected to the conductive pillar in the second chip adjacent thereto and the rewiring layer, respectively.

In some embodiments, the second chips are sequentially stacked between the rewiring layer and the first chip in the thickness direction of the substrate layer, and a third conductive connection layer is disposed between any two adjacent ones of the second chips; the third conductive connection layer is connected to the conductive pillars in one of the second chips adjacent thereto.

In some embodiments, the rewiring layer includes a resistive area, a capacitive area, and an inductive area located between the substrate layer and the chip stacking layer; at least one resistive element is formed in the resistive area, at least one capacitive element is formed in the capacitive area, and at least one inductive element is formed in the inductive area; and
the resistive element and the capacitive element are each located in the rewiring layer, and the inductive element is at least partially located in the rewiring layer; the resistive element, the capacitive element, and the inductive element are electrically connected to the first chip and/or the one or more second chips in the at least one chip stacking unit, respectively.

In some embodiments, the chip package structure further includes a heat dissipation assembly and a second through-hole penetrating the first chip;
the heat dissipation assembly includes a first heat dissipation layer covering a side of the first chip away from the one or more second chips, a first heat conductive pillar filled in the second through-hole, and a second heat dissipation layer covering a side away from the rewiring layer of the second chip adjacent to the first chip, and two ends of the first heat conductive pillar are respectively connected to the first heat dissipation layer and the second heat dissipation layer.

In some embodiments, the second chips are sequentially stacked between the rewiring layer and the first chip in the thickness direction of the substrate layer, the chip package structure further includes a third through-hole penetrating at least some the second chips, the heat dissipation assembly further includes a second heat conductive pillar filled in the third through-hole, and the second heat dissipation layer is disposed on a side of each of the second chips away from the rewiring layer;
in any two adjacent ones of the second chips, the third through-hole is disposed at least in one of the second chips close to a side of the first chip, and two ends of the second heat conductive pillar are respectively connected to the second heat dissipation layer adjacent thereto.

In some embodiments, the first heat dissipation layer covers the side of the first chip away from the one or more second chips in a whole surface.

In some embodiments, the second chip includes a circuit area and at least one heat dissipation area adjacent to the circuit area, the conductive pillar is located in the circuit area, the second heat dissipation layer is located in the heat dissipation area, and the first heat conductive pillar and the second heat dissipation layer are overlapped.

In some embodiments, the first heat dissipation layer includes a first heat conductive layer and a first adhesive layer located between the first heat conductive layer and the first chip, and the first heat conductive pillar includes a second adhesive layer filled in a sidewall and a bottom portion of the second through-hole, and a second heat conductive layer surrounded by the second adhesive layer; the second heat dissipation layer includes a third heat conductive layer and a third adhesive layer located between the third heat conductive layer and the second chip;
the first heat conductive layer is connected to the second heat conductive layer, the first adhesive layer is connected to the second adhesive layer, and the second adhesive layer is connected to the second heat conductive layer.

In some embodiments, materials of the first adhesive layer, the second adhesive layer, and the third adhesive layer are same, and are selected from metal copper;
materials of the first heat conductive layer, the second heat conductive layer, and the third heat conductive layer are same, and are selected from molybdenum, titanium, or an alloy thereof.

In some embodiments, the rewiring layer includes a first wiring layer, a first dielectric layer, a second wiring layer, a second dielectric layer, a third wiring layer, and a third dielectric layer sequentially stacked on a side of the substrate layer close to the chip stacking layer;
the capacitive element includes a first electrode and a second electrode that are at least partially overlapped; the first electrode is located in any one of the first wiring layer, the second wiring layer, and the third wiring layer, and the second electrode is located in any one of the first wiring layer, the second wiring layer, and the third wiring layer different from the first electrode; the second electrode is electrically connected to the first chip and/or the one or more second chips in the at least one chip stacking unit;
the resistive element is located in any one of the first wiring layer, the second wiring layer, and the third wiring layer, and a side of the resistive element away from the substrate layer is electrically connected to the first chip and/or the one or more second chips in the at least one chip stacking unit; and
the inductive element includes a spiral coil, a portion of the spiral coil is located in at least one of the first wiring layer, the second wiring layer, and the third wiring layer, and another portion of the spiral coil penetrates the substrate layer and is extended to a side of the substrate layer away from the rewiring layer; one end of the spiral coil is electrically connected to the first chip and/or the one or more second chips in the at least one chip stacking unit.

In some embodiments, each coil of the spiral coils is at least located on the side of the substrate layer away from the rewiring layer, and located in the first wiring layer and the second wiring layer, and penetrates at least the substrate layer and the first dielectric layer;
a surface of the spiral coil located on the side of the substrate layer away from the rewiring layer is covered with a protective layer.

In some embodiments, the chip package structure further includes at least one welding portion located on the side of the substrate layer away from the rewiring layer, at least one first plunger penetrating the substrate layer, at least one second plunger penetrating the first dielectric layer, at least one third plunger penetrating the second dielectric layer, and at least one fourth plunger penetrating the third dielectric layer;
the first wiring layer includes a plurality of first signal bonding portions, at least a part of the plurality of first signal bonding portions are connected to the at least one first plunger, and at least a part of the plurality of first signal bonding portions are connected to the at least one second plunger; the second wiring layer includes a plurality of second signal bonding portions, at least a part of the plurality of second signal bonding portions are connected to the at least one second plunger, and at least a part of the plurality of second signal bonding portions are connected to the at least one third plunger; the third wiring layer includes a plurality of third signal bonding portions, at least a part of the plurality of third signal bonding portions are connected to the at least one third plunger, and at least a part of the plurality of third signal bonding portions are connected to the at least one fourth plunger;
the first plunger is connected in alignment with the welding portion, and the fourth plunger is connected to the first conductive connection portion or the second conductive connection portion; the welding portion is electrically connected to the first conductive connection portion or the second conductive connection portion through the first plunger, the first signal bonding portion, the second plunger, the second signal bonding portion, the third plunger, the third signal bonding portion, and the fourth plunger in sequence.

In some embodiments, the chip package structure further includes at least one welding portion located on the side of the substrate layer away from the rewiring layer;
a thickness of one of the at least one welding portion is greater than a thickness of any one of the first wiring layer, the second wiring layer, and the third wiring layer, and is greater than a sum of thicknesses of the inductive element and the protective layer located on the side of the substrate layer away from the rewiring layer.

In some embodiments, the first electrode is located in the first wiring layer, the second electrode is located in the second wiring layer, the first electrode is connected to one of the plurality of second signal bonding portions through one of the at least one second plunger, and the second electrode is electrically connected to the first conductive connection portion or the second conductive connection portion through one of the at least one third plunger, one of the plurality of third signal bonding portions, and one of the at least one fourth plunger in sequence;
the resistive element is located in the second wiring layer, a side of the resistive element close to the substrate layer is connected to one of the plurality of first signal bonding portions through one of the at least one second plunger, a side of the resistive element away from the substrate layer is connected to two ones of the plurality of third signal bonding portions through two ones of the at least one third plunger, and one of the two third signal bonding portions is electrically connected to the first conductive connection portion or the second conductive connection portion through one of the at least one fourth plunger;
the spiral coil of the inductive element is located on the side of the substrate layer away from the rewiring layer, located in the first wiring layer and the second wiring layer, and penetrates the substrate layer and the first dielectric layer; the spiral coil includes a signal transmission terminal located in the second wiring layer, and the signal transmission terminal is electrically connected to the first conductive connection portion or the second conductive connection portion through one of the at least one third plunger, one of the plurality of third signal bonding portions, and one of the at least one fourth plunger in sequence.

In some embodiments, the first chip and the one or more second chips each include any one of a glass-based chip and a silicon-based chip, and the substrate layer includes any one of a glass substrate and a silicon substrate.

A second aspect of the present disclosure provides a method for preparing a chip package structure, including:
preparing at least one chip stacking unit; the chip stacking unit includes a first chip and one or more second chips stacked on one side of the first chip, the second chip is provided with a first through-hole penetrating each second chips, a conductive pillar is filled in the first through-hole, any one of the first chip and the one or more second chips is connected to the conductive pillar in the second chip adjacent thereto, a side away from the first chip of the second chip located on a surface layer is provided with a first welding layer, and the conductive pillar is connected to the first welding layer;
providing a substrate layer, and subsequently forming a rewiring layer and a second welding layer which are stacked on one side of the substrate layer; and
welding the first welding layer and the second welding layer, so that the at least one chip stacking unit is welded on a side of the rewiring layer away from the substrate layer to form a chip stacking layer electrically connected to the rewiring layer; and the first chip is electrically connected to the second chip and/or the rewiring layer through the conductive pillar.

In some embodiments, a process for preparing the chip stacking unit includes following:
providing the first chip, and forming at least one second through-hole penetrating the first chip in the first chip;
forming a first heat dissipation layer and a third welding layer on opposite two sides of the first chip, respectively, and filling a first heat conductive pillar in the second through-hole; the third welding layer includes a first heat conductive welding portion and a first conductive welding portion, and two ends of the first heat conductive pillar are respectively connected to the first heat dissipation layer and the first heat conductive welding portion;
providing the one or more second chips, and forming at least one first through-hole penetrating the second chip;
forming a fourth welding layer and a first welding layer on opposite two sides of the second chip, respectively, and filling the conductive pillar in the at least one first through-hole; the fourth welding layer includes a second heat conductive welding portion and a second conductive welding portion, and the second conductive welding portion is connected to the conductive pillar; and
welding the third welding layer and the fourth welding layer to connect the first heat conductive welding portion and the second heat conductive welding portion, and connect the first conductive welding portion and the second conductive welding portion to form the chip stacking unit.

In some embodiments, providing a substrate layer, and subsequently forming a rewiring layer and a second welding layer which are stacked on one side of the substrate layer includes following operations:
providing the substrate layer; the substrate layer includes a first surface and a second surface disposed oppositely;
forming a first wiring layer and a first dielectric layer that are stacked on the first surface of the substrate layer, and forming at least one welding portion and a partial structure of at least one inductive element on the second surface of the substrate layer; the first wiring layer includes a plurality of first signal bonding portions, each of the at least one welding portion is connected to one of the plurality of first signal bonding portions through a through-hole penetrating the substrate layer, and the at least one inductive element further penetrates the substrate layer and is located on the first wiring layer;
forming a second wiring layer, a second dielectric layer, a third wiring layer, and a third dielectric layer on the first dielectric layer in sequence to form the rewiring layer; the second wiring layer is electrically connected to the first wiring layer through a through-hole penetrating the first dielectric layer, the third wiring layer is electrically connected to the second wiring layer through a through-hole penetrating the second dielectric layer, at least one resistive element and at least one capacitive element are further formed in the rewiring layer, and the at least one inductive element is further located in the second wiring layer and penetrates the first dielectric layer; and
forming the second welding layer on the third dielectric layer; the second welding layer is electrically connected to the third wiring layer through a through-hole penetrating the third dielectric layer.

A third aspect of the present disclosure further provides an electronic device, and the electronic device includes any one of the chip package structures described above.

In the chip package structure, the method for preparing the chip package structure and the electronic device of the embodiments of the present disclosure, a first through-hole penetrating the second chip is formed on the second chip by a through-hole process, and a conductive pillar is filled in the first through-hole, so that an electrical connection between the first chip (the top chip) and the second chip (the bottom chip) and/or an electrical connection between the first chip (the top chip) and the rewiring layer is realized. In the present disclosure, a plurality of chips can be stereoscopically integrated to form a chip stacking unit, and a plurality of chip stacking units each containing multiple layers of chips can be integrated on the same substrate layer provided with a rewiring layer, which is beneficial to reduce the area occupied by a single chip on the substrate layer, thereby realizing high-density integration of the chips. In this case, a plurality of chips in each chip stacking unit can be interconnected by the conductive pillar, and any chip in each chip stacking unit can be interconnected with the rewiring layer by at least one conductive pillar. Therefore, the embodiments of the present disclosure realize high-density chip interconnection while realizing high-density chip integration, and thereby meeting the requirements of high-performance chips.

Other features and advantages of the present disclosure will be described in detail in the following detailed description.

### BRIEF DESCRIPTION OF THE DRAWINGS

In order to describe the technical solutions in the embodiments of the present disclosure more clearly, the accompanying drawings to be used in the description of the embodiments of the present disclosure will be briefly introduced below. It is apparent that the accompanying drawings described below are only some embodiments of the present disclosure, and for those skilled in the art, other drawings can be obtained from these drawings without making creative efforts.

In order to fully understand the present disclosure and beneficial effects thereof, the description will be given below in conjunction with the drawings, and the same reference numerals in the description below indicate the same parts in the drawings.

FIG. 1 is a schematic diagram of a cross-sectional structure of a chip package structure according to some embodiments of the present disclosure;

FIG. 2 is a schematic diagram of a cross-sectional structure of another chip package structure according to some embodiments of the present disclosure;

FIG. 3 is a top view of a first chip according to some embodiments of the present disclosure;

FIG. 4 is a top view of a second chip according to some embodiments of the present disclosure;

FIG. 5 is a top view of another second chip according to some embodiments of the present disclosure;

FIG. 6 is a flow diagram of a method for preparing a chip package structure according to some embodiments of the present disclosure;

FIG. 7 is a schematic diagram of a cross-sectional structure of a first chip when it is not welded according to some embodiments of the present disclosure;

FIG. 8 is a schematic diagram of a cross-sectional structure of a second chip when it is not welded according to some embodiments of the present disclosure;

FIG. 9 is a schematic diagram of a cross-sectional structure of another second chip when it is not welded according to some embodiments of the present disclosure;

FIG. 10 is a schematic diagram of a cross-sectional structure of a chip stacking unit formed by welding the first chip in FIG. 7 and the second chip in FIG. 8;

FIG. 11 is a schematic diagram of a cross-sectional structure of another chip stacking unit formed by welding the first chip in FIG. 7 and the second chip in FIG. 9;

FIG. 12 is a schematic diagram of a cross-sectional structure of a first wiring layer, a first dielectric layer, and a welding portion formed on two opposite sides of a substrate layer using a through-hole and a double-side process according to some embodiments of the present disclosure;

FIG. 13 is a schematic diagram of a cross-sectional structure of a rewiring layer and a second welding layer formed on the basis of the structure in FIG. 12;

FIG. 14 is a schematic diagram of a structure of an electronic device according to some embodiments of the present disclosure.

Description of the reference numerals:
1. Chip package structure; 2. Substrate layer; 3. Rewiring layer; 3a. First wiring layer; 3b. First dielectric layer; 3c. Second wiring layer; 3d. Second dielectric layer; 3e. Third wiring layer; 3f. Third dielectric layer; 4. Chip stacking layer; 5. Chip stacking unit; 6. First chip; 7 (7′). Second chip; 8. First through-hole; 9. Conductive pillar; 10. First conductive connection layer; 11. Second conductive connection layer; 11a. First conductive connection portion; 11b. Second conductive connection portion; 12. Third conductive connection layer; 13. Conductive layer; 14. Adhesive layer; 15. Resistive area; 16. Capacitive area; 17. Inductive area; 18. Resistive element; 19. Capacitive element; 19a. First electrode; 19b. Second electrode; 20. Inductive element; 20a. Spiral coil; 201a. First portion; 201b. Second portion; 201c. Third portion; 201d. Fourth portion; 201 e. Fifth portion; 21. Second through-hole; 22. Heat dissipation assembly; 22a. First heat dissipation layer; 22b. First heat conductive pillar; 22c. Second heat dissipation layer; 22d. Second heat conductive pillar; 23. Third through-hole; 24. Circuit area; 25. Heat dissipation area; 26. First heat conductive layer; 27. First adhesive layer; 28. Second adhesive layer; 29. Second heat conductive layer; 30. Third heat conductive layer; 31. Third adhesive layer; 32. Protective layer; 33. Welding portion; 34. First plunger; 35. Second plunger; 36. Third plunger; 37. Fourth plunger; 38. First signal bonding portion; 39. Second signal bonding portion; 40. Third signal bonding portion; 41. First welding layer; 41a. Third conductive welding portion; 41b. Fourth conductive welding portion; 42. Second welding layer; 42a. Fifth conductive welding portion; 42b. Sixth conductive welding portion; 43. Third welding layer; 43a. First heat conductive welding portion; 43b. First conductive welding portion; 44. Fourth welding layer; 44a. Second heat conductive welding portion; 44b. Second conductive welding portion; 45. First surface; 46. Second surface; 47. Electronic device; 48. Device body.

### DETAILED DESCRIPTION

The technical solutions in the embodiments of the present disclosure will be clearly and completely described below in conjunction with the accompanying drawings in the embodiments of the present disclosure. It is apparent that the embodiments described herein are only some of the embodiments of the present disclosure, but not all of the embodiments of the present disclosure. Based on the embodiments of the present disclosure, all other embodiments obtained by those skilled in the art without making creative efforts fall within the scope of protection of the present disclosure.

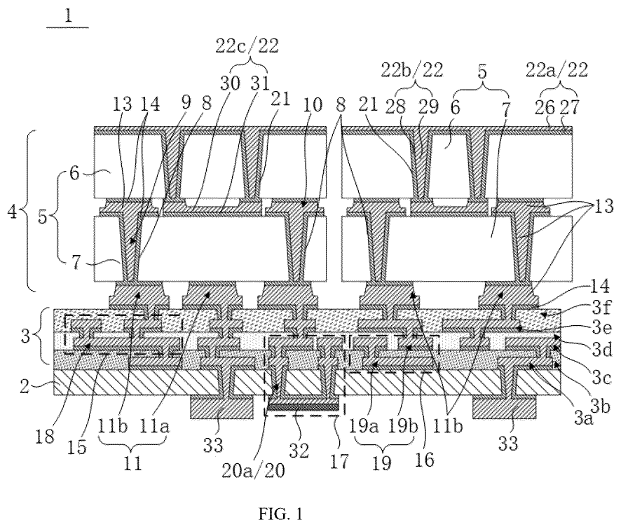

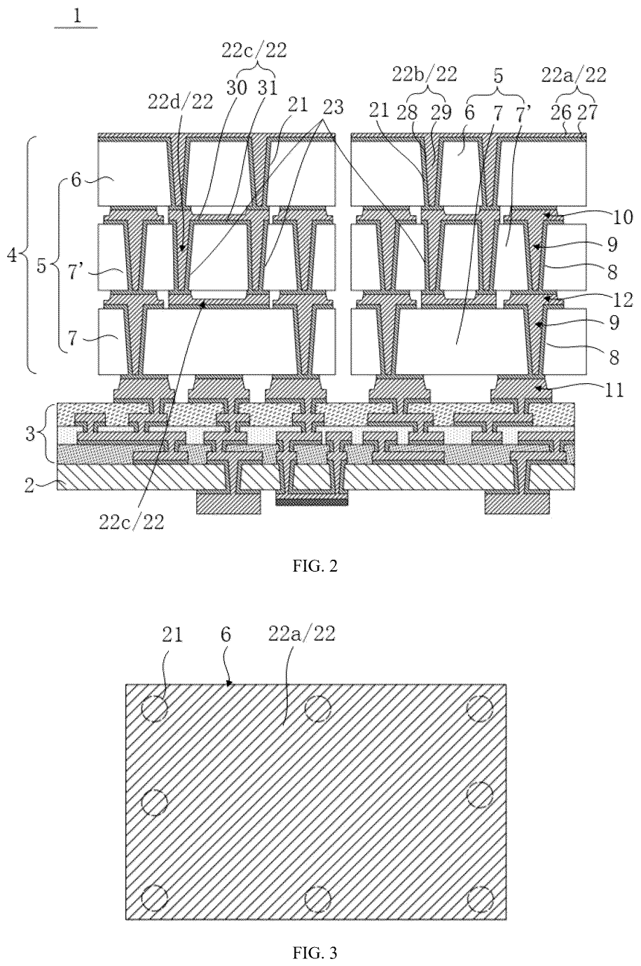

As shown in FIG. 1 and FIG. 2, some embodiments of the present disclosure provide a chip package structure 1, and the chip package structure 1 includes a substrate layer 2, a rewiring layer 3, and a chip stacking layer 4. The rewiring layer 3 is disposed on one side of the substrate layer 2; the chip stacking layer 4 is disposed on the side of the rewiring layer 3 away from the substrate layer 2, and includes at least one chip stacking unit 5. The chip stacking unit 5 includes a first chip 6, one or more second chips 7 (7′) located between the first chip 6 and the rewiring layer 3, and the first chip 6 and the one or more second chips 7 (7′) are at least partially overlapped in the thickness direction of the substrate layer 2.

The chip package structure 1 further includes at least one first through-hole 8 penetrating each second chip 7 (7′), a conductive pillar 9 is filled in the first through-hole 8, any one of the first chip and the one or more second chips is connected to the conductive pillar 9 in the second chip 7 (7′) adjacent thereto, and the first chip 6 is electrically connected to the second chip 7 (7′) and/or the rewiring layer 3 through the conductive pillar 9.

In the embodiments of the present disclosure, the first through-hole 8 penetrating the second chip 7 (7′) is formed in the second chip 7 (7′) by a through-hole process, and the conductive pillar 9 is filled in the first through-hole 8, so that an electrical connection between the first chip 6 (the top chip) and the second chip 7 (7′) (the bottom chip) and/or an electrical connection between the first chip 6 (the top chip) and the rewiring layer 3 is achieved. In the embodiments of the present disclosure, a plurality of chips can be stereoscopically integrated to form the chip stacking unit 5, and a plurality of chip stacking units 5 each containing multiple layers of chips can be integrated on the same substrate layer 2 provided with the rewiring layer 3, which is beneficial to reduce the area occupied by a single chip on the substrate layer 2, thereby realizing high-density integration of the chips. In this case, a plurality of chips in each chip stacking unit 5 can be interconnected by the conductive pillar 9, and any chip in each chip stacking unit 5 can be interconnected with the rewiring layer 3 by at least one conductive pillar 9. Therefore, the embodiments of the present disclosure realize high-density chip interconnection while realizing high-density chip integration, and thereby meeting the requirements of high-performance chips.

In some embodiments, the first chip 6 and the second chip 7 (7′) are both glass-based chips. It is apparent that in other embodiments, the first chip 6 and the second chip 7 (7′) may also be silicon-based chips.

When both the first chip 6 and the second chip 7 (7′) are glass-based chips, the first through-hole 8 can be formed by a glass punching process, so as to facilitate the puncturing on the second chip 7 (7′).

In some embodiments, as shown in FIG. 1 and FIG. 2, a first conductive connection layer 10 is disposed between the first chip 6 and the adjacent second chip 7 (7′), and the first conductive connection layer 10 is connected to the conductive pillar 9 in the adjacent second chip 7 (7′). A second conductive connection layer 11 is disposed between the second chip 7 close to the rewiring layer 3 and the rewiring layer 3, and the second conductive connection layer 11 includes a first conductive connection portion 11a and a second conductive connection portion 11b that are located between the corresponding second chip 7 and the rewiring layer 3 and are spaced apart. The first conductive connection portion 11a is electrically connected to the adjacent second chip 7 and the rewiring layer 3, respectively, and the second conductive connection portion 11b is electrically connected to the conductive pillar 9 in the adjacent second chip 7 and the rewiring layer 3, respectively.

It can be understood that the first chip 6 and the adjacent second chip 7 (7′) are electrically connected through the first conductive connection layer 10, and can also be electrically connected through the first conductive connection layer 10 and the conductive pillar 9. The first chip 6 can be electrically connected to the rewiring layer 3 through the first conductive connection layer 10, the conductive pillar 9 in at least one second chip 7 (7′), and the second conductive connection layer. The second chip 7 close to the rewiring layer 3 can be electrically connected to the rewiring layer 3 through the first conductive connection portion 11a.

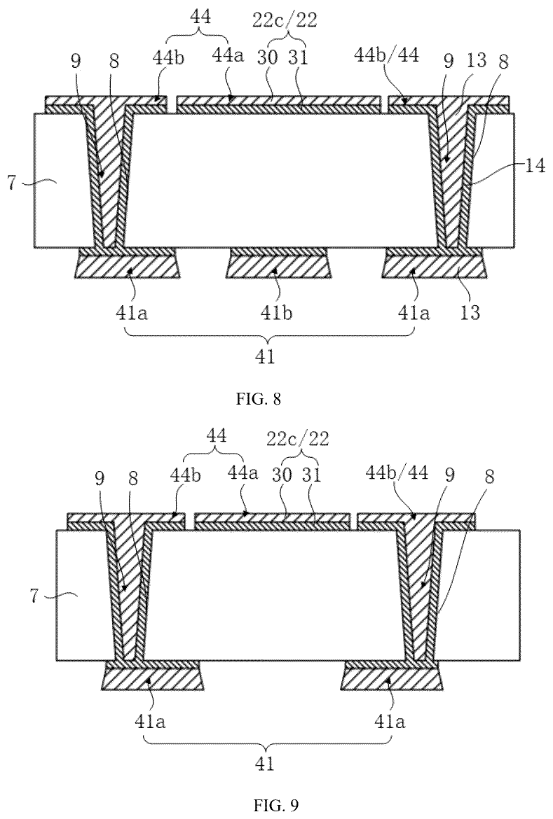

It should be noted that the quantity and types of conductive connection portions between each chip stacking unit 5 and the rewiring layer 3 can be the same or different; and which are not limited by the embodiments of the present disclosure. For example, two chip stacking units 5 are integrated in the chip package structure 1 in FIG. 1, the chip stacking unit 5 at the left side is connected to the rewiring layer 3 through the first conductive connection portion 11a and the second conductive connection portion 11b, and the chip stacking unit 5 at the right side is connected to the rewiring layer 3 only through the second conductive connection portion 11b. Correspondingly, when manufacturing the second chip 7, two types of second chips 7 as shown in FIG. 8 and FIG. 9 can be manufactured, and the second chip 7 shown in FIG. 8 and the second chip 7 shown in FIG. 9 are respectively applied to different chip stacking units 5.

In a specific embodiment, as shown in FIG. 1, only one second chip 7 is disposed between the first chip 6 and the rewiring layer 3, and then the first chip 6 can be electrically connected to the rewiring layer 3 through the first conductive connection layer 10, the conductive pillar 9 in the second chip 7, and the second conductive connection portion 11b in sequence.

In another specific embodiment, as shown in FIG. 2, a plurality of second chips (for example, the second chip 7 and the second chip 7′) are sequentially stacked between the rewiring layer 3 and the first chip 6 in the thickness direction of the substrate layer 2, and a third conductive connection layer 12 is disposed between any two adjacent second chips 7 and 7′. The third conductive connection layer 12 is connected to the conductive pillar 9 in the adjacent second chip 7 (7′).

It can be understood that when there are a plurality of second chips 7 (7′), the first chip 6 can be electrically connected to the rewiring layer 3 through the first conductive connection layer 10, the conductive pillars 9 in the plurality of second chips 7 (7′), the third conductive connection layer 12, and the second conductive connection portion 11b in sequence. The second chip 7′ located at the intermediate position can be electrically connected to the rewiring layer 3 through the conductive pillar 9 in at least one second chip 7 (7′), at least one third conductive connection layer 12, and the second conductive connection portion 11 b in sequence.

In some embodiments, the first conductive connection layer 10, the second conductive connection layer 11, and the third conductive connection layer 12 are all conductive connection layers formed after the welding layers are welded. It can be understood that the connection between the first chip 6 and the adjacent second chip 7 (7′), between any two adjacent second chips 7 (7′), and between the rewiring layer 3 and the adjacent second chip 7 are all connected by welding.

In a specific embodiment, the first conductive connection layer 10, the second conductive connection layer 11, and the third conductive connection layer 12 are each composed of a conductive layer 13 and an adhesive layer 14, and the adhesive layer 14 is located between the conductive layer 13 and the corresponding chip.

In some embodiments, the conductive pillar 9 is also composed of the conductive layer 13 and the adhesive layer 14, and specifically, the conductive pillar 9 is composed of the adhesive layer 14 formed on the sidewall of the first through-hole 8 and the conductive layer 13 surrounded by the adhesive layer 14.

In a specific embodiment, the material of the conductive layer 13 includes metallic copper, but which is not limited thereto. The material of the adhesive layer 14 includes molybdenum, titanium, or an alloy thereof, but which is not limited thereto.

In some embodiments, as shown in FIG. 1 and FIG. 13, the rewiring layer 3 includes a resistive area 15, a capacitive area 16, and an inductive area 17 located between the substrate layer 2 and the chip stacking layer 4. At least one resistive element 18 is formed in the resistive area 15, at least one capacitive element 19 is formed in the capacitive area 16, and at least one inductive element 20 is formed in the inductive area 17. Both the resistive element 18 and the capacitive element 19 are located in the rewiring layer 3, and the inductive element 20 is at least partially located in the rewiring layer 3. The resistive element 18, the capacitive element 19 and the inductive element 20 are respectively electrically connected to the first chip 6 and/or the second chip 7 (7′) in at least one chip stacking unit 5.

In the embodiments of the present disclosure, the resistive element 18, the capacitive element 19, and the inductive element 20 are integrated in the rewiring layer 3, so as to avoid additional welding of the external resistive element 18, the capacitive element 19, and the inductive element 20 on the substrate layer 2, thereby reducing the subsequent welding process and reducing the packaging area, which is beneficial to reducing the overall volume of the chip package structure 1.

In some embodiments, as shown in FIG. 1 and FIG. 2, the chip package structure 1 further includes a heat dissipation assembly 22, and a second through-hole 21 penetrating the first chip 6. The heat dissipation assembly 22 includes a first heat dissipation layer 22a covering the side of the first chip 6 away from the second chip 7 (7′), a first heat conductive pillar 22 b filled in the second through-hole 21, and a second heat dissipation layer 22c covering the side away from the rewiring layer 3 of the second chip 7 (7′) adjacent to the first chip 6, and two ends of the first heat conductive pillar 22b are respectively connected to the first heat dissipation layer 22a and the second heat dissipation layer 22c.

In the embodiments of the present disclosure, the second through-hole 21 is formed in the first chip 6 through a hole puncturing process, the first heat conductive pillar 22b is filled in the second through-hole 21, and in this case, the second heat dissipation layer 22c on the second chip 7 (7′) in the lower layer is in communication with the first heat dissipation layer 22a on the outside of the first chip 6 in the upper layer through the first heat conductive pillar 22b. In this way, the heat generated by the second chip 7 (7′) in the lower layer can be effectively discharged, so that the second chip 7 (7′) can be prevented from overheating during use, thereby addressing the heat dissipation problem caused by high-density interconnection of multiple chips and packaging of multiple layers of chips.

In some embodiments, as shown in FIG. 2, a plurality of second chips 7 (for example, the second chip 7 and the second chip 7′) are sequentially stacked between the rewiring layer 3 and the first chip 6 in the thickness direction of the substrate layer 2. The chip package structure 1 further includes a third through-hole 23 penetrating at least a part of the second chips 7 (7′), the heat dissipation assembly 22 further includes a second heat conductive pillar 22d filled in the third through-hole 23, and the second heat dissipation layer 22c is disposed on the side of each second chip 7 (7′) away from the rewiring layer 3. In any two adjacent second chips 7 (7′), the third through-hole 23 is at least disposed in the second chip 7 (7′) on the side close to the first chip 6, and two ends of the second heat conductive pillar 22d are respectively connected to the adjacent second heat dissipation layer 22c.

It can be understood that when there are a plurality of second chips, the third through-hole 23 can also be formed in the second chip 7′ by a hole puncturing process, and the second heat conductive pillar 22d is filled in third through-hole 23, so that two adjacent second chips 7 (7′) can be in communication with the first heat conductive pillar 22b through the second heat conductive pillar 22d and the second heat dissipation layer 22c, so as to effectively discharge the heat generated by each layer of the second chip 7 (7′).

It should be noted that the second chip 7 adjacent to the rewiring layer 3 may be not provided with the third through-hole 23, but which is not limited thereto. For example, when the rewiring layer 3 also needs to dissipate heat, the third through-hole 23 can be provided in the second chip 7 adjacent to the rewiring layer 3, and the third through-hole is filled with the second heat conductive pillar 22d. In the embodiments of the present disclosure, it is only taken as an example that the third through-hole 23 is not provided on the second chip 7 adjacent to the rewiring layer 3.

In some embodiments, as shown in FIG. 3, the first heat dissipation layer 22a covers the side of the first chip 6 away from the second chip 7 as a whole surface, so that the heat dissipation area is maximized, which is beneficial to improving the heat dissipation effect.

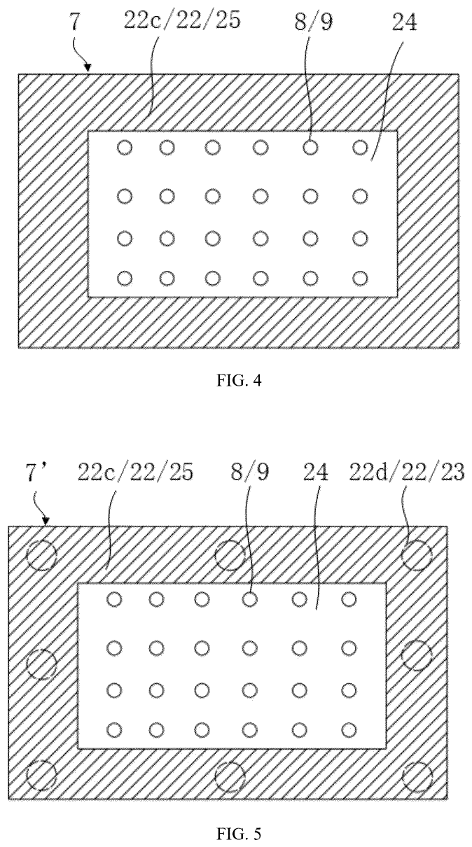

In some embodiments, as shown in FIG. 4 and FIG. 5, the second chip 7 (7′) includes a circuit area 24 and at least one heat dissipation area 25 adjacent to the circuit area 24. The conductive pillar 9 is located in the circuit area 24, the second heat dissipation layer 22c is located in the heat dissipation area 25, and the first heat conductive pillar 22b and the second heat dissipation layer 22c are overlapped. It can be understood that in addition to the circuit area 24 for signal transmission and power connection, at least one heat dissipation area 25 may be provided in the second chip 7 (7′) for heat dissipation connection with the chip disposed above.

In a specific embodiment, the heat dissipation area 25 is disposed around the circuit area 24, that is, the heat dissipation area 25 in the second chip 7 (7′) is located at an edge position, but which is not limited thereto.

It should be noted that the second chip 7 shown in FIG. 4 is not provided with the third through-hole 23, so that the second chip 7 shown in FIG. 4 can be applied to the chip package structure 1 shown in FIG. 1. The second chip 7′ shown in FIG. 5 is provided with the third through-hole 23, so that the second chip 7′ shown in FIG. 5 can be applied to the chip package structure 1 shown in FIG. 2.

In some embodiments, the first heat dissipation layer 22a includes a first heat conductive layer 26, and a first adhesive layer 27 located between the first heat conductive layer 26 and the first chip 6. The first heat conductive pillar 22b includes a second adhesive layer 28 filled on the sidewall and the bottom portion of the second through-hole 21, and a second heat conductive layer 29 surrounded by the second adhesive layer 28. The second heat dissipation layer 22c includes a third heat conductive layer 30, and a third adhesive layer 31 located between the third heat conductive layer 30 and the second chip 7. The first heat conductive layer 26 is connected to the second heat conductive layer 29, the first adhesive layer 27 is connected to the second adhesive layer 28, and the second adhesive layer 28 is connected to the second heat conductive layer 29.

It can be understood that the adhesive layer 14 can enhance the connection tightness between the heat conductive layer and the chip, which is beneficial to improving the heat dissipation effect.

In a specific embodiment, the materials of the first heat conductive layer 26, the second heat conductive layer 29, and the third heat conductive layer 30 are the same. For example, the materials of the first heat conductive layer 26, the second heat conductive layer 29, and the third heat conductive layer 30 are selected from metal copper having good heat dissipation performance, but which are not limited thereto.

In a specific embodiment, the materials of the first adhesive layer 27, the second adhesive layer 28, and the third adhesive layer 31 are the same. For example, the materials of the first adhesive layer 27, the second adhesive layer 28, and the third adhesive layer 31 are selected from molybdenum, titanium, or an alloy thereof, but which is not limited thereto.

It can be understood that the first adhesive layer 27 and the second adhesive layer 28 may be formed in the same manufacturing process, and the first heat conductive layer 26 and the second heat conductive layer 29 may be formed in the same manufacturing process, which is beneficial to simplify the manufacturing process.

In some embodiments, the materials and structures of the second heat conductive pillar 22d and the first heat conductive pillar 22b are the same, but which are not limited thereto.

It can be understood that the materials of the heat conductive layer (for example, the first heat conductive layer 26, the second heat conductive layer 29, and the third heat conductive layer 30), the conductive connection layer (for example, the first conductive connection layer 10, the second conductive connection layer 11, and the third conductive connection layer 12), the conductive pillar 9, and the heat conductive pillar (for example, the first heat conductive pillar 22b and the second heat conductive pillar 22d) in the embodiments of the present disclosure may be the same, thereby simplifying the manufacturing process. It is apparent that in other embodiments, the materials of the heat conductive layer, the conductive connection layer, the conductive pillar 9, and the heat conductive pillar may be different in order to take into account both the high heat conductive effect and the high conductive effect.

In some embodiments, as shown in FIG. 1, the rewiring layer 3 includes a first wiring layer 3a, a first dielectric layer 3b, a second wiring layer 3c, a second dielectric layer 3d, a third wiring layer 3e, and a third dielectric layer 3f subsequently stacked on the side of the substrate layer 2 close to the chip stacking layer 4.

It should be noted that the first wiring layer 3a, the second wiring layer 3c, and the third wiring layer 3e are conductive connection layers, while the first dielectric layer 3b, the second dielectric layer 3d, and the third dielectric layer 3f are insulating layers. It can be understood that the number of wiring layers and dielectric layers in the rewiring layer 3 is not limited to three layers, and the number of layers may be increased according to the needs of the circuit structure.

In some embodiments, the materials of the first wiring layer 3a, the second wiring layer 3c, and the third wiring layer 3e are the same, and are the same as the materials of the first conductive connection layer 10, the second conductive connection layer 11, and the third conductive connection layer 12. That is, the first wiring layer 3a, the second wiring layer 3c, and the third wiring layer 3e can also be composed of the conductive layer 13 and the adhesive layer 14. The adhesive layer 14 in the first wiring layer 3a is located between the corresponding conductive layer 13 and the first dielectric layer 3b, the adhesive layer 14 in the second wiring layer 3c is located between the corresponding conductive layer 13 and the second dielectric layer 3d, and the adhesive layer 14 in the third wiring layer 3e is located between the corresponding conductive layer 13 and the third dielectric layer 3f.

It can be understood that the materials of the wiring layer and the conductive connection layer are the same to simplify the process.

In some embodiments, the capacitive element 19 includes a first electrode 19a and a second electrode 19b disposed at least partially overlapped. The first electrode 19a is located in any one of the first wiring layer 3a, the second wiring layer 3c, and the third wiring layer 3e, and the second electrode is located in any one of the first wiring layer 3a, the second wiring layer 3c, and the third wiring layer 3e different from the first electrode 19a. The second electrode 19b is electrically connected to the first chip 6 and/or the second chip 7 (7′) in at least one chip stacking unit 5. By integrating the capacitive element 19 in the rewiring layer 3, the additional welding of the external capacitive element 19 on the substrate layer 2 can be avoided, which is beneficial to reduce the area and volume of the chip package structure 1.

In some embodiments, the resistive element 18 is located in any one of the first wiring layer 3a, the second wiring layer 3c, and the third wiring layer 3e, and the side of the resistive element 18 away from the substrate layer 2 is electrically connected to the first chip 6 and/or the second chip 7 (7′) in at least one chip stack unit 5. By integrating the resistive element 18 in the rewiring layer 3, the additional welding of the external resistive element 18 on the substrate layer 2 can be avoided, which is beneficial to reduce the area and volume of the chip package structure 1.

In some embodiments, the inductive element 20 includes a spiral coil 20a, a portion of the spiral coil 20a is located in at least one of the first wiring layer 3a, the second wiring layer 3c, and the third wiring layer 3e, and the other portion of the spiral coil penetrates the substrate layer 2 and is extended to the side of the substrate layer 2 away from the rewiring layer 3. One end of the spiral coil 20a is electrically connected to the first chip 6 and/or the second chip 7 (7′) in at least one chip stacking unit 5. By integrating the inductive element 20 in the rewiring layer 3, the additional welding of the external inductive element 20 on the substrate layer 2 can be avoided, which is beneficial to reduce the area and volume of the chip package structure 1.

In some embodiments, each coil of the spiral coil 20a is located at least on the side of the substrate layer 2 away from the rewiring layer 3, located in the first wiring layer 3a and the second wiring layer 3c, and penetrates at least the substrate layer 2 and the first dielectric layer 3b. The surface of the spiral coil 20a located on the side of the substrate layer 2 away from the rewiring layer 3 is covered with a protective layer 32. The protective layer 32 is configured to isolate the portion of the inductive element 20 exposed to the outside to prevent oxidation.

It can be understood that the spiral coil 20a of the inductive element 20 in the embodiments of the present disclosure penetrates the substrate layer 2 and is partially embedded in the rewiring layer 3.

In a specific embodiment, the material of the protective layer 32 is selected from an ink of a particular color.

In some embodiments, the chip package structure 1 further includes at least one welding portion 33 located on the side of the substrate layer 2 away from the rewiring layer 3. The thickness of the welding portion 33 is greater than the thickness of any one of the wiring layers in the rewiring layer 3, and is greater than the sum of the thicknesses of the inductive element 20 and the protective layer 32 located on the side of the substrate layer 2 away from the rewiring layer 3. This design can prevent the situation of mistakenly welding to positions that do not require welding (such as the position where the inductive element 20 is located) during welding, thereby improving the welding yield.

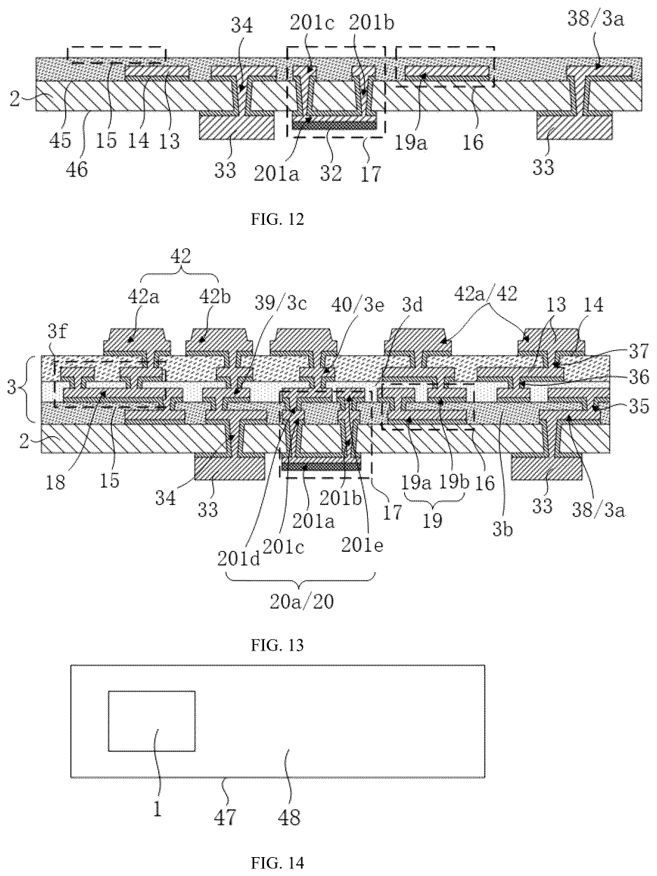

In some embodiments, with reference to FIG. 1, FIG. 12, and FIG. 13, the chip package structure 1 further includes at least one first plunger 34 penetrating the substrate layer 2, at least one second plunger 35 penetrating the first dielectric layer 3b, at least one third plunger 36 penetrating the second dielectric layer 3d, and at least one fourth plunger 37 penetrating the third dielectric layer 3f. The first wiring layer 3a includes a plurality of first signal bonding portions 38, and at least a part of the first signal bonding portions 38 are connected to the first plunger 34, and at least a part of the first signal bonding portions 38 are connected to the second plunger 35. The second wiring layer 3c includes a plurality of second signal bonding portions 39, at least a part of the second signal bonding portions 39 are connected to the second plunger 35, and at least a part of the second signal bonding portions 39 are connected to the third plunger 36. The third wiring layer 3e includes a plurality of third signal bonding portions 40, at least a part of the third signal bonding portions 40 are connected to the third plunger 36, and at least a part of the third signal bonding portions 40 are connected to the fourth plunger 37.

The first plunger 34 is connected to the welding portion 33 in alignment, and the fourth plunger 37 is connected to the first conductive connection portion 11a or the second conductive connection portion 11b. The welding portion 33 is electrically connected to the first conductive connection portion 11a or the second conductive connection portion 11b through the first plunger 34, the first signal bonding portion 38, the second plunger 35, the second signal bonding portion 39, the third plunger 36, the third signal bonding portion 40, and the fourth plunger 37 in sequence.

It can be understood that each welding portion 33 is electrically connected to the first conductive connection portion 11a or the second conductive connection portion 11b through the rewiring layer 3, so as to realize the electrical connection with the first chip 6 and/or the second chip 7, thereby realizing the signal input or output. Further, the welding portion 33 is configured to achieve the connection of the chip package structure 1 with other electronic devices or circuit structures.

In some embodiments, the first plunger 34 and the first wiring layer 3a may be formed in the same manufacturing process, the second plunger 35 and the second wiring layer 3c may be formed in the same manufacturing process, the third plunger 36 and the third wiring layer 3e may be formed in the same manufacturing process, and the fourth plunger 37 and the second welding layer 42 hereinafter may be formed in the same manufacturing process.

In a specific embodiment, as shown in FIG. 13, the first electrode 19a is located in the first wiring layer 3a, the second electrode 19b is located in the second wiring layer 3c. The first electrode 19a is connected to one second signal bonding portion 39 through one second plunger 35, and the second electrode 19b is electrically connected to the first conductive connection portion 11a or the second conductive connection portion 11b through one third plunger 36, one third signal bonding portion 40, and one fourth plunger 37 in sequence. The resistive element 18 is located in the second wiring layer 3c, the side of the resistive element 18 close to the substrate layer 2 is connected to one first signal bonding portion 38 through one second plunger 35, the side of the resistive element 18 away from the substrate layer 2 is connected to two third signal bonding portions 40 through two third plungers 36, and one of the third signal bonding portions 40 is electrically connected to the first conductive connection portion 11a or the second conductive connection portion 11b through one fourth plunger 37. The spiral coil 20a of the inductive element 20 is located on the side of the substrate layer 2 away from the rewiring layer 3, located in the first wiring layer 3a and the second wiring layer 3c, and penetrates the substrate layer 2 and the first dielectric layer 3b. The spiral coil 20a includes a signal transmission terminal located in the second wiring layer 3c, and the signal transmission terminal is electrically connected to the first conductive connection portion 11a or the second conductive connection portion 11b through one third plunger 36, one third signal bonding portion 40, and one fourth plunger 37 in sequence.

In a specific embodiment, as shown in FIG. 13, each turn of coil includes a first portion 201a located on the side of the substrate layer 2 away from the rewiring layer 3, two second portions 201b penetrating the substrate layer, two third portions 201c located in the first wiring layer 3a, two fourth portions 201d penetrating the first dielectric layer 3b, and two fifth portions 201e located in the second wiring layer 3c. The two second portions 201b are respectively connected to two ends of the first portion 201a, the two third portions 201c are respectively connected in one-to-one alignment to the two second portions 201b, the two fourth portions 201d are respectively connected in one-to-one alignment to the two third portions 201c, and the two fifth portions 201e are respectively connected in one-to-one alignment to the two fourth portions 201d. The first portion 201a, the second portions 201b, the third portions 201c, the fourth portions 201d, and the fifth portions 201e are connected to form a coil that perpendicularly penetrates the substrate layer 2 and the first dielectric layer 3b.

It is apparent that in other embodiments, the spiral coil 20a of the inductive element 20 may be formed only in any one of the first wiring layer 3a, the second wiring layer 3c, and the third wiring layer 3e.

It can be understood that through the hole puncturing and the double-side process, the welding layer and the rewiring layer 3 are respectively disposed on two opposite sides of the substrate layer 2, in this case, the capacitive area 16, the resistive area 15 and the inductive area 17 are formed, and the capacitive element 19, the resistive element 18 and the inductive element 20 are integrated in the chip package structure 1, so as to avoid additional welding of the external resistive element 18, the capacitive element 19 and the inductive element 20 on the substrate layer 2, thereby reducing the subsequent welding process, and reducing the occupied area of the package, which is beneficial to reduce the overall volume of the chip package structure 1.

In some embodiments, the substrate layer 2 includes any one of a glass substrate and a silicon substrate.

In a specific embodiment, the substrate layer 2 is a glass substrate, and since the glass substrate has the advantages of large size, good heat dissipation, low dielectric constant and dielectric loss, the embodiments of the present disclosure can realize a chip package with large size, high performance inductance, high frequency application, lower dielectric loss and energy saving.

In the embodiments of the present disclosure, on the one hand, the first through-hole 8 penetrating the second chip 7 (7′) is formed in the second chip 7 (7′) by a through-hole process, and the conductive pillar 9 is filled in the first through-hole 8, so that an electrical connection between the first chip 6 (the top chip) and the second chip 7 (7′) (the bottom chip) and/or an electrical connection between the first chip 6 (the top chip) and the rewiring layer 3 is realized, thereby achieving high-density interconnection of chips while achieving high-density integration of chips. On the other hand, the second through-hole 21 is formed in the first chip 6 through a hole puncturing process, the first heat conductive pillar 22b is filled in the second through-hole 21, and in this case, the second heat dissipation layer 22c on the second chip 7 (7′) in the lower layer is in communication with the first heat dissipation layer 22a on the outside of the first chip 6 in the upper layer through the first heat conductive pillar 22b. In this way, the heat generated by the second chip 7 (7′) in the lower layer can be effectively discharged, so that the second chip 7 (7′) can be prevented from overheating during use, thereby addressing the heat dissipation problem caused by high-density interconnection of multiple chips and packaging of multiple layers of chips. On still another hand, through the through-hole and the double-side process, the welding layer and the rewiring layer 3 are respectively disposed on two opposite sides of the substrate layer 2, in this case, the capacitive area 16, the resistive area 15 and the inductive area 17 are formed, and the capacitive element 19, the resistive element 18 and the inductive element 20 are integrated in the chip package structure 1, so as to avoid additional welding of the external resistive element 18, the capacitive element 19 and the inductive element 20 on the substrate layer 2, thereby reducing the subsequent welding process, and reducing the occupied area of the package, which is beneficial to reduce the overall volume of the chip package structure 1.

Therefore, the embodiments of the present disclosure can realize high-density integration and interconnection of chips on a smaller substrate layer 2, and can solve the heat dissipation problem caused by high-density interconnection and packaging of multiple chips, thereby meeting the requirements of high-performance chips.

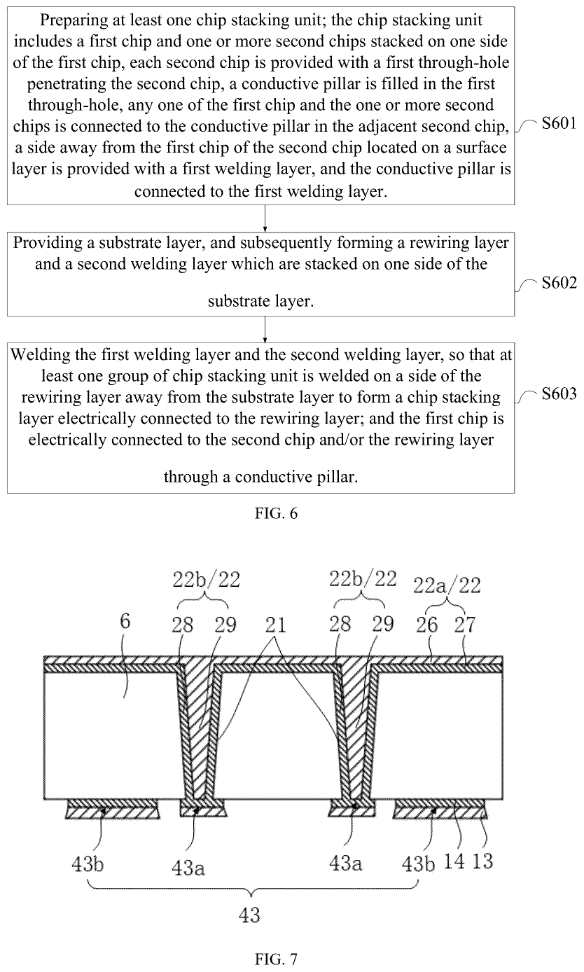

As shown in FIG. 6 to FIG. 13, some embodiments of the present disclosure further provide a method for preparing the chip package structure 1 in the embodiments described above, and the method includes steps S601 to S603.

S601: preparing at least one chip stacking unit; the chip stacking unit includes a first chip and one or more second chips stacked on one side of the first chip, each second chip is provided with a first through-hole penetrating the second chip, a conductive pillar is filled in the first through-hole, any one of the first chip and the one or more second chips is connected to the conductive pillar in the adjacent second chip, a side away from the first chip of the second chip located on a surface layer is provided with a first welding layer, and the conductive pillar is connected to the first welding layer.

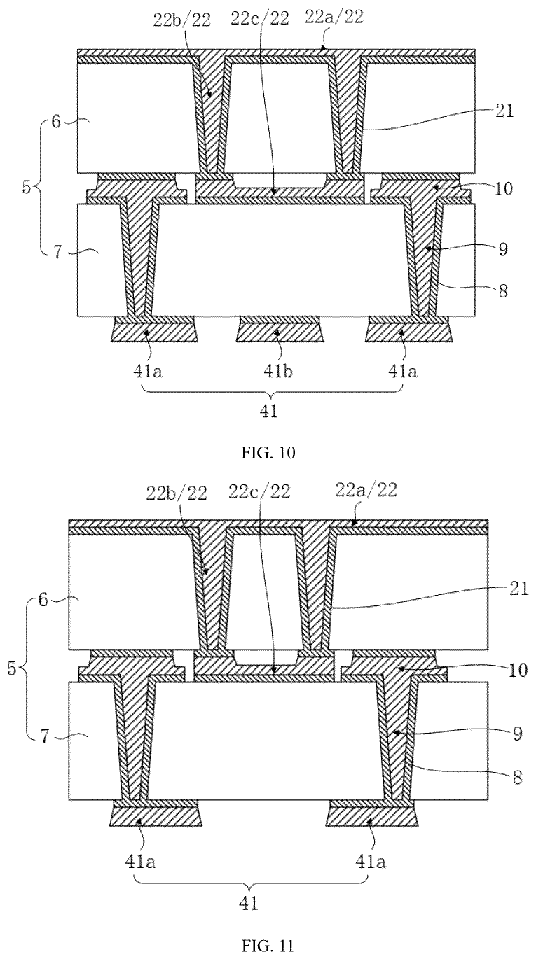

As shown in FIG. 10 and FIG. 11, the chip stacking unit 5 includes a first chip 6 and one or more second chips 7 stacked on one side of the first chip 6, each second chip 7 is provided with a first through-hole 8 penetrating the second chip 7, and a conductive pillar 9 is filled in the first through-hole 8. Any one chip of the first chip and the one or more second chips is connected to the conductive pillar 9 in the adjacent second chip 7, the side away from the first chip 6 of the second chip 7 located on the surface layer is provided with a first welding layer 41, and the conductive pillar 9 is connected to the first welding layer 41.

It can be understood that the number of chip stacking units 5 is not limited in the embodiments of the present disclosure.

In some embodiments, in step S601, the process for preparing each chip stacking unit 5 includes the following steps.

As shown in FIG. 7, a first chip 6 is provided, and at least one second through-hole 21 penetrating the first chip 6 is formed in the first chip 6.

As shown in FIG. 7, a first heat dissipation layer 22a and a third welding layer 43 are formed on two opposite sides of the first chip 6, respectively, and a first heat conductive pillar 22b is filled in the second through-hole 21. The third welding layer 43 includes a first heat conductive welding portion 43a and a first conductive welding portion 43b, and two ends of the first heat conductive pillar 22b are connected to the first heat dissipation layer 22a and the first heat conductive welding portion 43a, respectively.

As shown in FIG. 8 or FIG. 9, a second chip 7 is provided, and at least one first through-hole 8 penetrating the second chip 7 is formed in the second chip 7.

As shown in FIG. 8 or FIG. 9, a fourth welding layer 44 and a first welding layer 41 are formed on two opposite sides of the second chip 7, respectively, and a conductive pillar 9 is filled in the first through-hole 8. The fourth welding layer 44 includes a second heat conductive welding portion 44a and a second conductive welding portion 44b, and the second conductive welding portion 44b is connected to the conductive pillar 9.

As shown in FIG. 10 or FIG. 11, the third welding layer 43 and the fourth welding layer 44 are welded to connect the first heat conductive welding portion 43a and the second heat conductive welding portion 44a, and connect the first conductive welding portion 43b and the second conductive welding portion 44b to form the chip stacking unit 5.

It can be understood that the first conductive welding portion 43b and the second conductive welding portion 44b are welded to form the first conductive connection layer 10 in the embodiments described above, the first heat conductive welding portion 43a and the second heat conductive welding portion 44a are welded to form the second heat dissipation layer 22c, and the related description of the first conductive connection layer 10 and the second heat dissipation layer 22c can refer to the embodiments described above, and which will not be described herein again. Moreover, the difference between the two kinds of chip stacking units 5 shown in FIG. 10 and FIG. 11 is only in that the structure of the first welding layer 44 is different, and the two kinds of chip stacking units 5 can be disposed in the same chip package structure 1.

In some embodiments, the first chip 6 and the second chip 7 are both glass-based chips. It is apparent that in other embodiments, the first chip 6 and the second chip 7 may also be silicon-based chips.

When both the first chip 6 and the second chip 7 are glass-based chips, the first through-hole 8 can be formed by a glass punching process, so as to facilitate the puncturing on the second chip 7.

It should be noted that in the embodiments of the present disclosure, the process for preparing the chip stacking unit 5 is illustrated by taking the number of the second chips 7 as one as an example. When the number of the second chips 7 is multiple, a similar process is adopted to provide through-holes in the second chips 7 (7′) to realize signal connection and/or heat dissipation connection between the upper and lower chips.

In the embodiments of the present disclosure, by using a lamination method and puncturing holes in the chips, the connection of internal electrical signals and the connection of heat dissipation are realized, and thereby realizing the effect of effectively dissipating heat of the internal chip or the underlying chip while realizing signal interconnection of multiple layers of chips.

S602: providing a substrate layer, and subsequently forming a rewiring layer and a second welding layer which are stacked on one side of the substrate layer.

As shown in FIG. 12 and FIG. 13, the rewiring layer 3 and the second welding layer 42 which are stacked are sequentially formed on one side of the substrate layer 2.

In some embodiments, S602 includes the following steps.

As shown in FIG. 12, the substrate layer 2 is provided; and the substrate layer 2 includes a first surface 45 and a second surface 46 that are disposed oppositely.

As shown in FIG. 12, the first wiring layer 3a and the first dielectric layer 3b that are stacked are formed on the first surface 45 of the substrate layer 2, and at least one welding portion 33 and a part of the structure of at least one inductive element 20 are formed on the second surface 46 of the substrate layer 2. The first wiring layer 3a includes a plurality of first signal bonding portions 38, the welding portion 33 is connected to the first signal bonding portion 38 through one through-hole penetrating the substrate layer 2, and the inductive element 20 further penetrates the substrate layer 2 and is located in the first wiring layer 3a.

As shown in FIG. 13, a second wiring layer 3c, a second dielectric layer 3d, a third wiring layer 3e, and a third dielectric layer 3f are sequentially formed on the first dielectric layer 3b to form the rewiring layer 3. The second wiring layer 3c is electrically connected to the first wiring layer 3a through a through-hole penetrating the first dielectric layer 3b, the third wiring layer 3e is electrically connected to the second wiring layer 3c through a through-hole penetrating the second dielectric layer 3d. At least one resistive element 18 and at least one capacitive element 19 are further formed in the rewiring layer 3, and the inductive element 20 can be further located in the second wiring layer 3c and penetrate the first dielectric layer 3b.

As shown in FIG. 13, a second welding layer 42 is formed on the third dielectric layer 3f; and the second welding layer 42 is electrically connected to the third wiring layer 3e through a through-hole penetrating the third dielectric layer 3f.

In some embodiments, the substrate layer 2 includes any one of a glass substrate and a silicon substrate.

In a specific embodiment, the substrate layer 2 is a glass substrate, and since the glass substrate has the advantages of large size, good heat dissipation, low dielectric constant and dielectric loss, the embodiments of the present disclosure can realize a chip package with large size, high performance inductance, high frequency application, lower dielectric loss and energy saving.

In some embodiments, the surface of the inductive element 20 located on the second surface 46 of the substrate layer 2 is covered by a protective layer 32. In a specific embodiment, the protective layer 32 is an ink of a particular color.

Since the connecting areas on both the upper and lower sides of the substrate layer 2 provided with the rewiring layer 3 are covered by the welding layer, and the inductive area 17 is covered by the protective layer 32, the connecting areas of the substrate layer 2 and the rewiring layer 3 can be effectively isolated, thereby achieving an anti-oxidation effect.

The structures of the rewiring layer 3 and the welding portion 33 can be referred to the description of embodiments described above, and which will not be described herein again.

In the embodiments of the present disclosure, the preparation of the welding portion 33, the resistive element 18, the capacitive element 19, and the inductive element 20 are achieved by using the hole puncturing and double-side process, and the resistive element 18, the capacitive element 19, and the inductive element 20 are integrated in the rewiring layer 3, so as to avoid additional welding of the external resistive element 18, the capacitive element 19, and the inductive element 20 on the substrate layer 2, thereby reducing the subsequent welding process and reducing the packaging area, which is beneficial to reducing the overall volume of the chip package structure 1.

S603: welding the first welding layer and the second welding layer, so that at least one chip stacking unit is welded on a side of the rewiring layer away from the substrate layer to form a chip stacking layer electrically connected to the rewiring layer; and the first chip is electrically connected to the second chip and/or the rewiring layer through a conductive pillar.

It can be understood that the first welding layer 41 and the second welding layer 42 are welded to form the second conductive connection layer 11 shown in FIG. 1.

Specifically, as shown in FIG. 10, the first welding layer 41 includes a third conductive welding portion 41a and a fourth conductive welding portion 41b, and the second welding layer 42 includes a fifth conductive welding portion 42a and a sixth conductive welding portion 42b disposed in one-to-one alignment with the third conductive welding portion 41a and the fourth conductive welding portion 41b. The third conductive welding portion 41a is connected to the conductive pillar 9 in the second chip 7, and the fourth conductive welding portion 41b is connected to the second chip 7. The third conductive welding portion 41a and the fifth conductive welding portion 42a are welded to form the second conductive connection portion 11b in the embodiments described above, and the fourth conductive welding portion 41b and the sixth conductive welding portion 42b are welded to form the first conductive connection portion 11a in the embodiments described above.

As shown in FIG. 11, the bottom portion of the second chip 7 in another chip stacking unit 5 is provided with only the third conductive welding portion 41a, but the present disclosure is not limited thereto.

It can be understood that the number of conductive welding portions (conductive connection portions) between each chip stacking unit 5 and the rewiring layer 3 can be the same or different; and which not limited in the embodiments of the present disclosure.

In the embodiments of the present disclosure, high-density integration and interconnection of chips can be achieved on a smaller substrate layer 2 through a through-hole and double-side process, and the heat dissipation problem caused by high-density interconnection and packaging of multiple chips can be solved, thereby meeting the demand of high-performance chips.

As shown in FIG. 14, some embodiments of the present disclosure further provide an electronic device 47, and the electronic device 47 includes a device body 48 and at least one chip package structure 1 provided in the embodiments described above. The chip package structure 1 is electrically connected to the device body 48.

It can be understood that the chip package structure 1 can be electrically connected to other electronic devices or circuit structures in the device body 48 through the welding portion 33 disposed at the bottom portion of the substrate layer 2, thereby realizing signal connection.

In some embodiments, the electronic device 47 may be a display device or an artificial intelligent (AI) product, which is not limited in the present disclosure.

In the description of the present disclosure, the terms “first”, “second” and the like are used for descriptive purposes only and are not to be construed as indicating or implying relative importance or implying an amount of indicated technical features. Therefore, features defined with “first” and “second” may explicitly or implicitly include one or more of the features. In the description of the present disclosure, the term “a plurality of” refers to two or more unless otherwise specifically defined.

In the above embodiments, each embodiment is described with its own emphasis. For parts that are not described in detail in a certain embodiment, reference can be made to the relevant descriptions of other embodiments.

The embodiments, implementations and related technical features of the present disclosure can be combined and replaced with each other without conflict.

The above embodiments are merely preferred embodiments of the present disclosure, and do not limit the present disclosure in any form. Any simple modification, equivalent change and embellishment to the above embodiments based on the technical essence of the present disclosure without departing from the content of the technical solution of the present disclosure still fall within the scope of the technical solution of the present disclosure.

What is claimed is:

1. A chip package structure comprising:
a substrate layer;
a rewiring layer disposed on one side of the substrate layer; and
a chip stacking layer disposed on a side of the rewiring layer away from the substrate layer and comprising at least one chip stacking unit; wherein the chip stacking unit comprises a first chip and one or more second chips located between the first chip and the rewiring layer, and the first chip and the one or more second chips are at least partially overlapped in a thickness direction of the substrate layer;
wherein the chip package structure further comprises at least one first through-hole penetrating each second chip, a conductive pillar is filled in the first through-hole, any one of the first chip and the one or more second chips is connected to the conductive pillar in the second chip adjacent thereto, and the first chip is electrically connected to the second chip and/or the rewiring layer through the conductive pillar.

2. The chip package structure according to claim 1, wherein a first conductive connection layer is disposed between the first chip and the second chip adjacent thereto, and the first conductive connection layer is connected to the conductive pillar in the second chip adjacent thereto;
wherein a second conductive connection layer is disposed between the second chip close to the rewiring layer and the rewiring layer, and the second conductive connection layer comprises a first conductive connection portion and a second conductive connection portion that are located between a corresponding second chip and the rewiring layer and are spaced apart; wherein the first conductive connection portion is electrically connected to the second chip adjacent thereto and the rewiring layer, respectively, and the second conductive connection portion is electrically connected to the conductive pillar in the second chip adjacent thereto and the rewiring layer, respectively.

3. The chip package structure according to claim 2, wherein the second chips are sequentially stacked between the rewiring layer and the first chip in the thickness direction of the substrate layer, and a third conductive connection layer is disposed between any two adjacent ones of the second chips; wherein the third conductive connection layer is connected to the conductive pillar in the second chip adjacent thereto.

4. The chip package structure according to claim 1, wherein the rewiring layer comprises a resistive area, a capacitive area, and an inductive area located between the substrate layer and the chip stacking layer; wherein at least one resistive element is formed in the resistive area, at least one capacitive element is formed in the capacitive area, and at least one inductive element is formed in the inductive area; and
wherein the resistive element and the capacitive element are each located in the rewiring layer, and the inductive element is at least partially located in the rewiring layer; wherein the resistive element, the capacitive element, and the inductive element are electrically connected to the first chip and/or the one or more second chips in the at least one chip stacking unit, respectively.

5. The chip package structure according to claim 4, wherein the rewiring layer comprises a first wiring layer, a first dielectric layer, a second wiring layer, a second dielectric layer, a third wiring layer, and a third dielectric layer sequentially stacked on a side of the substrate layer close to the chip stacking layer;
wherein the capacitive element comprises a first electrode and a second electrode that are at least partially overlapped; the first electrode is located in any one of the first wiring layer, the second wiring layer, and the third wiring layer, and the second electrode is located in any one of the first wiring layer, the second wiring layer, and the third wiring layer different from the first electrode; wherein the second electrode is electrically connected to the first chip and/or the one or more second chips in the at least one chip stacking unit;
wherein the resistive element is located in any one of the first wiring layer, the second wiring layer, and the third wiring layer, and a side of the resistive element away from the substrate layer is electrically connected to the first chip and/or the one or more second chips in the at least one chip stacking unit; and
wherein the inductive element comprises a spiral coil, a portion of the spiral coil is located in at least one of the first wiring layer, the second wiring layer, and the third wiring layer, and another portion of the spiral coil penetrates the substrate layer and is extended to a side of the substrate layer away from the rewiring layer; one end of the spiral coil is electrically connected to the first chip and/or the one or more second chips in the at least one chip stacking unit.

6. The chip package structure according to claim 5, wherein each coil of the spiral coils is at least located on the side of the substrate layer away from the rewiring layer, and located in the first wiring layer and the second wiring layer, and penetrates at least the substrate layer and the first dielectric layer;
wherein a surface of the spiral coil located on the side of the substrate layer away from the rewiring layer is covered with a protective layer.

7. The chip package structure according to claim 6, wherein the chip package structure further comprises at least one welding portion located on the side of the substrate layer away from the rewiring layer;
wherein a thickness of one of the at least one welding portion is greater than a thickness of any one of the first wiring layer, the second wiring layer, and the third wiring layer, and is greater than a sum of thicknesses of the inductive element and the protective layer located on the side of the substrate layer away from the rewiring layer.

8. The chip package structure according to claim 5, wherein the chip package structure further comprises at least one welding portion located on the side of the substrate layer away from the rewiring layer, at least one first plunger penetrating the substrate layer, at least one second plunger penetrating the first dielectric layer, at least one third plunger penetrating the second dielectric layer, and at least one fourth plunger penetrating the third dielectric layer;
wherein the first wiring layer comprises a plurality of first signal bonding portions, at least a part of the plurality of first signal bonding portions are connected to the at least one first plunger, and at least a part of the plurality of first signal bonding portions are connected to the at least one second plunger; the second wiring layer comprises a plurality of second signal bonding portions, at least a part of the plurality of second signal bonding portions are connected to the at least one second plunger, and at least a part of the plurality of second signal bonding portions are connected to the at least one third plunger; the third wiring layer comprises a plurality of third signal bonding portions, at least a part of the plurality of third signal bonding portions are connected to the at least one third plunger, and at least a part of the plurality of third signal bonding portions are connected to the at least one fourth plunger;
wherein the first plunger is connected in alignment with the welding portion, and the fourth plunger is connected to the first conductive connection portion or the second conductive connection portion; the welding portion is electrically connected to the first conductive connection portion or the second conductive connection portion through the first plunger, the first signal bonding portion, the second plunger, the second signal bonding portion, the third plunger, the third signal bonding portions, and the fourth plunger in sequence.

9. The chip package structure according to claim 8, wherein the first electrode is located in the first wiring layer, the second electrode is located in the second wiring layer, the first electrode is connected to one of the plurality of second signal bonding portions through one of the at least one second plunger, and the second electrode is electrically connected to the first conductive connection portion or the second conductive connection portion through one of the at least one third plunger, one of the plurality of third signal bonding portions, and one of the at least one fourth plunger in sequence;
wherein the resistive element is located in the second wiring layer, a side of the resistive element close to the substrate layer is connected to one of the plurality of first signal bonding portions through one of the at least one second plunger, a side of the resistive element away from the substrate layer is connected to two ones of the plurality of third signal bonding portions through two ones of the at least one third plunger, and one of the two third signal bonding portions is electrically connected to the first conductive connection portion or the second conductive connection portion through one of the at least one fourth plunger;
wherein the spiral coil of the inductive element is located on the side of the substrate layer away from the rewiring layer, located in the first wiring layer and the second wiring layer, and penetrates the substrate layer and the first dielectric layer; wherein the spiral coil comprises a signal transmission terminal located in the second wiring layer, and the signal transmission terminal is electrically connected to the first conductive connection portion or the second conductive connection portion through one of the at least one third plunger, one of the plurality of third signal bonding portions, and one of the at least one fourth plunger in sequence.

10. The chip package structure according to claim 1, wherein the chip package structure further comprises a heat dissipation assembly and a second through-hole penetrating the first chip;
wherein the heat dissipation assembly comprises a first heat dissipation layer covering a side of the first chip away from the one or more second chips, a first heat conductive pillar filled in the second through-hole, and a second heat dissipation layer covering a side away from the rewiring layer of the second chip adjacent to the first chip, and two ends of the first heat conductive pillar are respectively connected to the first heat dissipation layer and the second heat dissipation layer.

11. The chip package structure according to claim 10, wherein the second chips are sequentially stacked between the rewiring layer and the first chip in the thickness direction of the substrate layer, the chip package structure further comprises a third through-hole penetrating at least some of the second chips, the heat dissipation assembly further comprises a second heat conductive pillar filled in the third through-hole, and the second heat dissipation layer is disposed on a side of each of the second chips away from the rewiring layer;
wherein in any two adjacent ones of the second chips, the third through-hole is disposed at least in one of the second chips close to a side of the first chip, and two ends of the second heat conductive pillar are respectively connected to the second heat dissipation layer adjacent thereto.

12. The chip package structure according to claim 10, wherein the first heat dissipation layer covers the side of the first chip away from the one or more second chips in a whole surface.

13. The chip package structure according to claim 10, wherein the second chip comprises a circuit area and at least one heat dissipation area adjacent to the circuit area, the conductive pillar is located in the circuit area, the second heat dissipation layer is located in the heat dissipation area, and the first heat conductive pillar and the second heat dissipation layer are overlapped.

14. The chip package structure according to claim 10, wherein the first heat dissipation layer comprises a first heat conductive layer and a first adhesive layer located between the first heat conductive layer and the first chip, and the first heat conductive pillar comprises a second adhesive layer filled in a sidewall and a bottom portion of the second through-hole, and a second heat conductive layer surrounded by the second adhesive layer; wherein the second heat dissipation layer comprises a third heat conductive layer and a third adhesive layer located between the third heat conductive layer and the second chip;
wherein the first heat conductive layer is connected to the second heat conductive layer, the first adhesive layer is connected to the second adhesive layer, and the second adhesive layer is connected to the second heat conductive layer.

15. The chip package structure according to claim 14, wherein materials of the first adhesive layer, the second adhesive layer, and the third adhesive layer are same, and are selected from metal copper;
wherein materials of the first heat conductive layer, the second heat conductive layer, and the third heat conductive layer are same, and are selected from molybdenum, titanium, or an alloy thereof.

16. The chip package structure according to claim 1, wherein the first chip and the one or more second chips each comprise any one of a glass-based chip and a silicon-based chip, and the substrate layer comprises any one of a glass substrate and a silicon substrate.

17. A method for preparing a chip package structure comprising:
preparing at least one chip stacking unit; wherein the chip stacking unit comprises a first chip and one or more second chips stacked on one side of the first chip, the second chip is provided with a first through-hole penetrating each second chip, a conductive pillar is filled in the first through-hole, any one of the first chip and the one or more second chips is connected to the conductive pillar in the second chip adjacent thereto, a side away from the first chip of the second chip located on a surface layer is provided with a first welding layer, and the conductive pillar is connected to the first welding layer;
providing a substrate layer, and subsequently forming a rewiring layer and a second welding layer which are stacked on one side of the substrate layer; and
welding the first welding layer and the second welding layer, so that the at least one chip stacking unit is welded on a side of the rewiring layer away from the substrate layer to form a chip stacking layer electrically connected to the rewiring layer; and the first chip is electrically connected to the one or more second chips and/or the rewiring layer through the conductive pillar.

18. The method for preparing a chip package structure according to claim 17, wherein a process for preparing the chip stacking unit comprises following:
providing the first chip, and forming at least one second through-hole penetrating the first chip in the first chip;
forming a first heat dissipation layer and a third welding layer on opposite two sides of the first chip, respectively, and filling a first heat conductive pillar in the second through-hole; wherein the third welding layer comprises a first heat conductive welding portion and a first conductive welding portion, and two ends of the first heat conductive pillar are respectively connected to the first heat dissipation layer and the first heat conductive welding portion;
providing the one or more second chips, and forming at least one first through-hole penetrating each second chip;
forming a fourth welding layer and a first welding layer on opposite two sides of the second chip, respectively, and filling the conductive pillar in the at least one first through-hole; wherein the fourth welding layer comprises a second heat conductive welding portion and a second conductive welding portion, and the second conductive welding portion is connected to the conductive pillar; and
welding the third welding layer and the fourth welding layer to connect the first heat conductive welding portion and the second heat conductive welding portion, and connect the first conductive welding portion and the second conductive welding portion to form the chip stacking unit.

19. The method for preparing a chip package structure according to claim 17, wherein providing a substrate layer, and subsequently forming a rewiring layer and a second welding layer which are stacked on one side of the substrate layer comprises following steps:
providing the substrate layer, wherein the substrate layer comprises a first surface and a second surface disposed oppositely;
forming a first wiring layer and a first dielectric layer that are stacked on the first surface of the substrate layer, and forming at least one welding portion and a partial structure of at least one inductive element on the second surface of the substrate layer; wherein the first wiring layer comprises a plurality of first signal bonding portions, each of the at least one welding portion is connected to one of the plurality of first signal bonding portions through a through-hole penetrating the substrate layer, and the at least one inductive element further penetrates the substrate layer and is located on the first wiring layer;
forming a second wiring layer, a second dielectric layer, a third wiring layer, and a third dielectric layer on the first dielectric layer in sequence to form the rewiring layer; wherein the second wiring layer is electrically connected to the first wiring layer through a through-hole penetrating the first dielectric layer, the third wiring layer is electrically connected to the second wiring layer through a through-hole penetrating the second dielectric layer, at least one resistive element and at least one capacitive element are further formed in the rewiring layer, and the at least one inductive element is further located in the second wiring layer and penetrates the first dielectric layer; and
forming the second welding layer on the third dielectric layer, wherein the second welding layer is electrically connected to the third wiring layer through a through-hole penetrating the third dielectric layer.

20. An electronic device comprising a chip package structure, wherein the chip package structure comprises:
a substrate layer;
a rewiring layer disposed on one side of the substrate layer; and
a chip stacking layer disposed on a side of the rewiring layer away from the substrate layer and comprising at least one chip stacking unit; wherein the chip stacking unit comprises a first chip and one or more second chips located between the first chip and the rewiring layer, and the first chip and the one or more second chips are at least partially overlapped in a thickness direction of the substrate layer;
wherein the chip package structure further comprises at least one first through-hole penetrating each second chip, a conductive pillar is filled in the first through-hole, any one of the first chip and the one or more second chips is connected to the conductive pillar in the second chip adjacent thereto, and the first chip is electrically connected to the second chip and/or the rewiring layer through the conductive pillar.
